(19) United States
(12) Patent Application Publication
(10) Pub. No.: US 2009/0302324 A1
(43) Pub. Date: Dec. 10, 2009

(54) Thin film transistor panel

(75) Inventors: Kai-Li Jiang, Beijing (CN); Qun-Qing Li, Beijing (CN); Shou-Shan Fan, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: Tsinghua University, Beijing City (CN); HON HAI Precision Industry CO., LTD., Tu-Cheng City (TW)

(21) Appl. No.: 12/384,244

(22) Filed: Apr. 2, 2009

(30) Foreign Application Priority Data
Jun. 4, 2008 (CN) 200810067639.6

(51) Int. Cl. H01L 33/00

(52) U.S. Cl. 257/72; 257/E33.053

(57) ABSTRACT

A thin film transistor panel includes an insulating substrate. The insulating substrate includes a number of parallel source lines, a number of parallel gate lines crossed with the source lines, and a number of girds defined by the source lines and the gate lines. Each of the girds includes a pixel electrode and a thin film transistor. The thin film transistor includes a source electrode, a drain electrode, a semiconducting layer, and a gate electrode. The source electrode is connected with one of the source lines defining the grid. The drain electrode is spaced from the source electrode and connected with the pixel electrode. The semiconducting layer is connected with the source electrode and the drain electrode. The semiconducting layer includes a semiconducting carbon nanotube layer. The gate electrode is connected with one of the gate lines defining the grid.

### RELATED APPLICATIONS

This application is related to commonly-assigned applications entitled, “METHOD FOR MAKING THIN FILM TRANSISTOR”, filed ______, (Atty. Docket No. US18067); “METHOD FOR MAKING THIN FILM TRANSISTOR”, filed ______, (Atty. Docket No. US17879); “THIN FILM TRANSISTOR”, filed ______, (Atty. Docket No. US18904); “THIN FILM TRANSISTOR”, filed ______, (Atty. Docket No. US19808); “THIN FILM TRANSISTOR”, filed ______, (Atty. Docket No. US18909); “THIN FILM TRANSISTOR”, filed ______, (Atty. Docket No. US18907); “THIN FILM TRANSISTOR”, filed ______, (Atty. Docket No. US18908); “THIN FILM TRANSISTOR”, filed ______, (Atty. Docket No. US18911); “THIN FILM TRANSISTOR”, filed ______, (Atty. Docket No. US18910); “THIN FILM TRANSISTOR”, filed ______, (Atty. Docket No. US18936); “METHOD FOR MAKING THIN FILM TRANSISTOR”, filed ______, (Atty. Docket No. US19871); “THIN FILM TRANSISTOR”, filed ______, (Atty. Docket No. US20078). The disclosures of the above-identified applications are incorporated herein by reference.

### BACKGROUND

1. Field of the Invention

The present invention relates to thin film transistor panels and, particularly, to a carbon nanotube based thin film transistor panel.

2. Discussion of Related Art

A flat panel display, such as a liquid crystal display (LCD) and an organic light emitting display (OLED), includes a thin film transistor (TFT) panel to individually control a plurality of pixels. The thin film transistor panel includes a plurality of pixels arranged in a matrix, and a plurality of signal lines to drive the pixels, such as gate lines for transmitting scanning signals and data lines for transmitting data signals. Each pixel includes a pixel electrode, and a TFT connected with the gate lines and the data lines to control the data signals. A gate insulating layer and a passivation layer are formed between the gate and data lines and the thin film transistor to insulate therebetween.

The thin film transistor includes gate electrodes connected with the gate lines, source electrode connected with the data lines, drain electrodes connected with the pixel electrodes, semiconductors in which a channel of the thin film transistor is formed, and a gate insulating layer between the gate electrode and the semiconductors. The thin film transistor performs a switching operation by modulating an amount of carriers accumulated in an interface between the insulation layer and the semiconducting layer from an accumulation state to a depletion state, with applied voltage to the gate electrode, to change an amount of the current passing between the drain electrode and the source electrode.

In related art, the material of the semiconducting layer is amorphous silicone (a-Si), poly-silicone (p-Si), or organic semiconducting material. The carrier mobility of an a-Si TFT is relatively lower than a p-Si TFT, and which induce a relatively lower response speed of the a-Si TFT. However, the method for producing the p-Si TFT is complicated and has a high cost. The organic TFT is flexible but has a relatively lower carrier mobility. Thus, the thin film transistor panel including the amorphous silicone or the poly-silicone TFTs is inflexible and unable to be used in a flexible display, the thin film transistor panel including the organic TFTs is flexible but has a relatively lower carrier mobility, and lower response speed.

Carbon nanotubes (CNTs) are a novel carbonaceous material and received a great deal of interest since the early 1990s. Carbon nanotubes have interesting and potentially useful heat conducting, electrical conducting, and mechanical properties. Further, there are two kinds of carbon nanotubes, metallic carbon nanotubes and semiconducting carbon nanotubes, that are determined by the arrangement of the carbon atoms therein. The carrier mobility of a single semiconducting carbon nanotube along a length direction thereof can reach about 1000 to 1500 cm²V⁻¹s⁻¹.

What is needed, therefore, is a low cost thin film transistor panel having relatively higher carrier mobility and response speed, and can be used in an flexible display.

### BRIEF DESCRIPTION OF THE DRAWINGS

Many aspects of the present thin film transistor panel can be better understood with references to the following drawings. The components in the drawings are not necessarily drawn to scale, the emphasis instead being placed upon clearly illustrating the principles of the present thin film transistor panel.

FIG. 1 is a top view of a thin film transistor panel in accordance with a first embodiment.

FIG. 2 is a cross sectional view along a line II-II of the thin film transistor panel of FIG. 1.

FIG. 3 shows a Scanning Electron Microscope (SEM) image of a carbon nanotube film containing entangled carbon nanotubes used in the thin film transistor of FIG. 1.

FIG. 4 shows a Scanning Electron Microscope (SEM) image of a pressed carbon nanotube film containing disordered aligned carbon nanotubes used in the thin film transistor of FIG. 1.

FIG. 5 shows a Scanning Electron Microscope (SEM) image of a carbon nanotube film containing ultra-long carbon nanotubes used in the thin film transistor of FIG. 1.

FIG. 6 shows a Scanning Electron Microscope (SEM) image of a drawn carbon nanotube film containing carbon nanotubes joined end to end used in the thin film transistor of FIG. 1.

FIG. 7 is a structural schematic of a carbon nanotube segment in the drawn carbon nanotube film.

FIG. 8 is a top view of a thin film transistor panel in accordance with a second embodiment.

FIG. 9 is a cross sectional view along a line VIII-VIII of the thin film transistor panel of FIG. 8.

Corresponding reference characters indicate corresponding parts throughout the several views. The exemplifications set out herein illustrate at least one embodiment of the present thin film transistor panel, in at least one form, and such exemplifications are not to be construed as limiting the scope of the invention in any manner.

### DETAILED DESCRIPTION OF EXEMPLARY EMBODIMENTS

References will now be made to the drawings to describe, in detail, embodiments of the present thin film transistor.

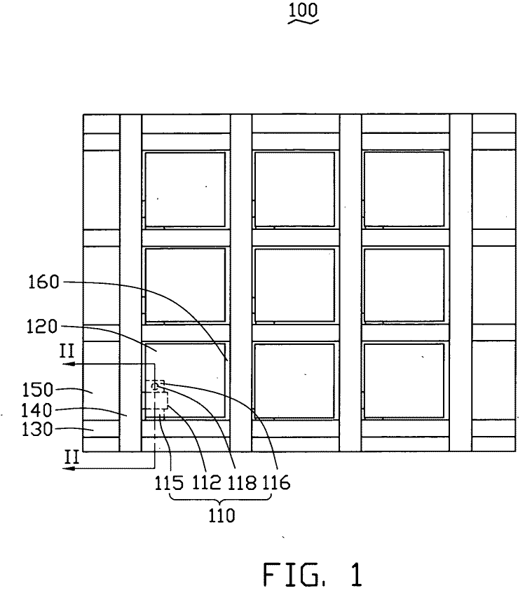

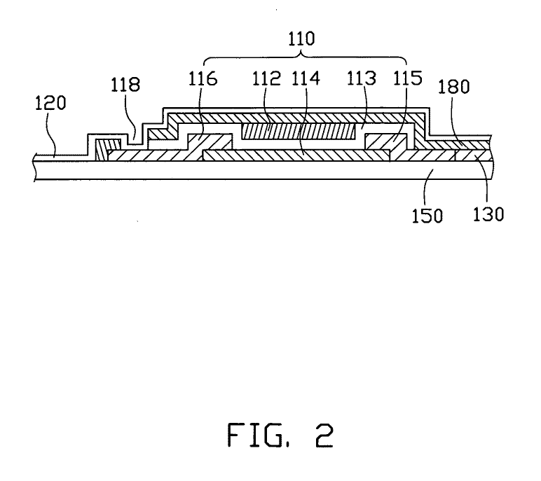

Referring to FIGS. 1 and 2, a thin film transistor panel 100 includes a plurality of thin film transistors 110, a plurality of pixel electrodes 120, a plurality of source lines 130 (i.e., data lines), a plurality of gate lines 140, and an insulating substrate 150.

The thin film transistors 110, pixel electrode 120, source lines 130, and gate lines 140 are all coplanar and disposed on a same surface of the insulating substrate 150. The source lines 130 are spaced with each other and arranged parallel along an X direction. The gate lines 140 are spaced with each other and arranged parallel along a Y direction. The X direction is perpendicular to the Y direction. Thus, the surface of the insulating substrate 150 is divided into a matrix of grid regions 160. The pixel electrodes 120 and the thin film transistors 110 are separately disposed in the grid regions 160. The pixel electrodes 120 are spaced with each other. The thin film transistors 110 are spaced from each other. Each grid region 160 contains one thin film transistor 110 and one pixel electrode 120 stacked or spaced apart from each other. In the present embodiment, in each grid region 160, the pixel electrode 120 covers the thin film transistor 110.

In the first embodiment, the thin film transistor 110 has a top gate structure. The thin film transistor 110 includes a semiconducting layer 114, a source electrode 115, a drain electrode 116, an insulating layer 113, and a gate electrode 112.

The semiconducting layer 114 is disposed on the insulating substrate 150. The source electrode 115 and the drain electrode 116 are spaced with each other and electrically connected to the semiconducting layer 114. The insulating layer 113 is disposed between the semiconducting layer 114 and the gate electrode 112. The insulating layer 113 is disposed on the semiconducting layer 114. Alternatively, the insulating layer 113 covers the semiconducting layer 114, the source electrode 115, and the drain electrode 116. The gate electrode 112 is disposed on the insulating layer 113. The gate electrode 112 is disposed above the semiconducting layer 114 and insulated from the semiconducting layer 114, the source electrode 115, and the drain electrode 116 by the insulating layer 113. A channel is defined in the semiconducting layer 114 at a region between the source electrode 115 and the drain electrode 116.

The source electrode 115 and the drain electrode 116 can be disposed on the semiconducting layer 114 or on the insulating substrate 150. More specifically, the source electrode 115 and the drain electrode 116 can be disposed on a top surface of the semiconducting layer 114, and at a same side of the semiconducting layer 114 as the gate electrode 112. In other embodiments, the source electrode 115 and the drain electrode 116 can be disposed on the insulating substrate 150 and covered by the semiconducting layer 114. In other embodiments, the source electrode 115 and the drain electrode 116 can be formed on the insulating substrate 150, and formed coplanar with the semiconducting layer 114.

The pixel electrode 120 is electrically connected with the drain electrode 116 of the thin film transistor 110. More specifically, a passivation layer 180 can be further disposed on the thin film transistor 110. The passivation layer 180 covers the thin film transistor 110 and defines a through hole 118 to expose the drain electrode 116 of the thin film transistor 110. The pixel electrode 120 covers the entire grid region 160 and the thin film transistor 110 therein, and electrically connects to the drain electrode 116 at the through hole 118. Other part of the thin film transistor 110 except the drain electrode 116 is insulated from the pixel electrode 120 by the passivation layer 180. The material of the passivation layer 180 can be a rigid material such as silicon nitride (Si3N4) or silicon dioxide (SiO2), or a flexible material such as polyethylene terephthalate (PET), benzocyclobutenes (BCB), or acrylic resins.

Each source electrode 115 of the thin film transistor 110 is electrically connected with one source line 130. More specifically, the source electrodes 115 of each line along the X direction of the thin film transistors 110 are electrically connected with one source line 130 near the thin film transistors 110.

Each gate electrode 112 of the thin film transistor 110 is electrically connected with one gate line 140. More specifically, the gate electrodes 112 of each line along the Y direction of the thin film transistors 110 are electrically connected with one gate line 140 near the thin film transistors 110.

The insulating substrate 150 is provided for supporting the thin film transistor 110. The material of the insulating substrate 150 can be the same as a substrate of a printed circuit board (PCB), and can be selected from rigid materials (e.g., p-type or n-type silicon, silicon with an silicon dioxide layer formed thereon, glass, crystal, crystal with a oxide layer formed thereon), or flexible materials (e.g., plastic or resin). In the present embodiment, the material of the insulating substrate is glass. The shape and size of the insulating substrate 150 is arbitrary.

The pixel electrodes 120 are conductive films made of a conductive material. When the pixel electrodes 120 is used in the liquid crystal displays, the materials of the pixel electrodes 120 can be selected from the group consisting of indium tin oxide (ITO), antimony tin oxide (ATO), indium zinc oxide (IZO), conductive polymer, and metallic carbon nanotubes. An area of each pixel electrode 120 can be in a range of about 10 square micrometers to 0.1 square millimeters. In the present embodiment, the material of the pixel electrode 120 is ITO, the area thereof is about 0.05 square millimeters.

The materials of the source lines 130 and the drain lines 140 are conductive, and can be selected from the group consisting of metal, alloy, silver paste, conductive polymer, or metallic carbon nanotube wires. The metal or alloy can be selected from the group consisting of aluminum (Al), copper (Cu), tungsten (W), molybdenum (Mo), gold (Au), titanium (Ti), neodymium (Nd), palladium (Pd), cesium (Cs), and combinations thereof. A width of the source lines 130 and the gate lines 140 can be in the range from about 0.5 nanometers to about 100 micrometers. In the present embodiment, the material of the source lines 130 and the gate lines 140 is Al, the width of the source lines 130 and the gate lines 140 is about 10 micrometers.

The semiconducting layer 114 includes a carbon nanotube layer. The carbon nanotube layer includes a plurality of single-walled carbon nanotubes or double-walled carbon nanotubes. The carbon nanotubes are semiconducting. Diameters of the single-walled carbon nanotubes range from about 0.5 nanometers to about 50 nanometers. Diameters of the double-walled carbon nanotubes range from about 1 nanometer to about 50 nanometers. In the present embodiment, the carbon nanotubes are single-walled carbon nanotubes with the diameter less than 10 micrometers.

More specifically, the carbon nanotube layer includes one carbon nanotube film or a plurality of stacked carbon nanotube films. The carbon nanotube film is formed by a plurality of carbon nanotubes having a uniform thickness, the carbon nanotubes in the carbon nanotube film can be orderly arranged or non-systematically arranged. The carbon nanotube film can be an ordered film or a disordered film.

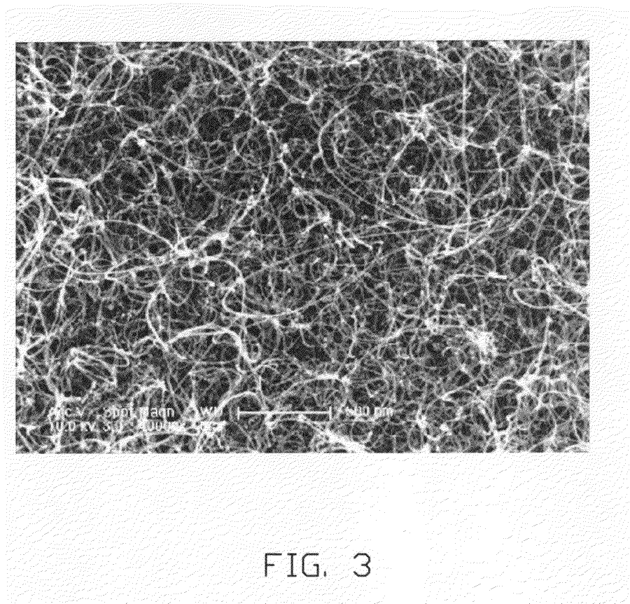

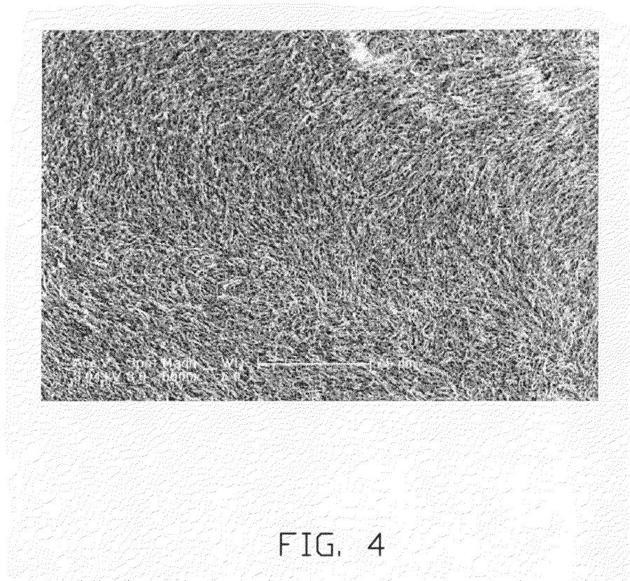

Referring to FIG. 3, in one kind of the disordered film, the carbon nanotubes are relatively long, disordered, curved, and entangled with each other. Referring to FIG. 4, in another kind of the disordered film, the carbon nanotubes are disordered arranged to make the disordered film isotropy. The disordered arranged carbon nanotubes are substantially parallel to a surface of the carbon nanotube film.

In the ordered film, the carbon nanotubes are primarily oriented along a same direction in each film and parallel to a surface of the carbon nanotube film. Different stratums/layers of films can have the direction of the nanotubes offset from the nanotubes in other films. More specifically, the ordered carbon nanotube film can include ultra-long carbon nanotubes or can be a “drawn” carbon nanotube film which is drawn from a carbon nanotube array. The drawn carbon nanotube film includes a plurality of semiconducting carbon nanotubes joined end to end by van der Waals attractive force therebetween.

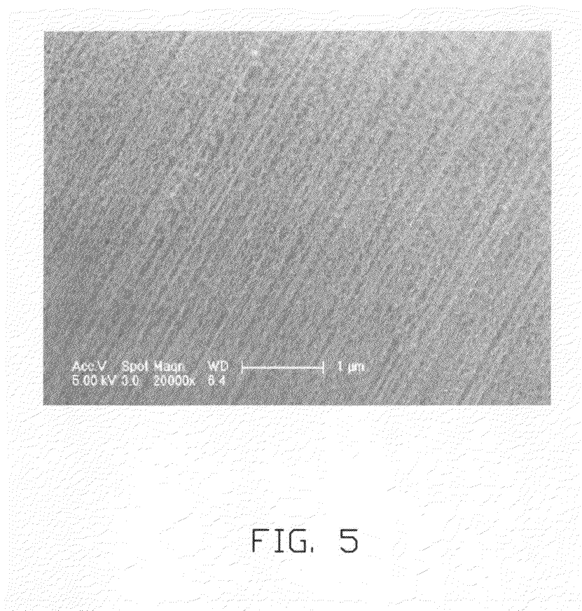

Referring to FIG. 5, the carbon nanotube film includes a plurality of ultra-long carbon nanotubes arranged along a preferred orientation. The ultra-long carbon nanotubes have lengths of about 10 centimeters or greater, comparing with the normal carbon nanotubes which have lengths of about several nanometers to several micron meters. The carbon nanotubes are parallel with each other, have almost equal length and are combined side by side by van der Waals attractive force therebetween. A length of the carbon nanotubes can reach up to several millimeters. The length of the film can be equal to the length of the carbon nanotubes. Such that at least one carbon nanotube will span the entire length of the carbon nanotube film. The length of the carbon nanotube film is only limited by the length of the carbon nanotubes.

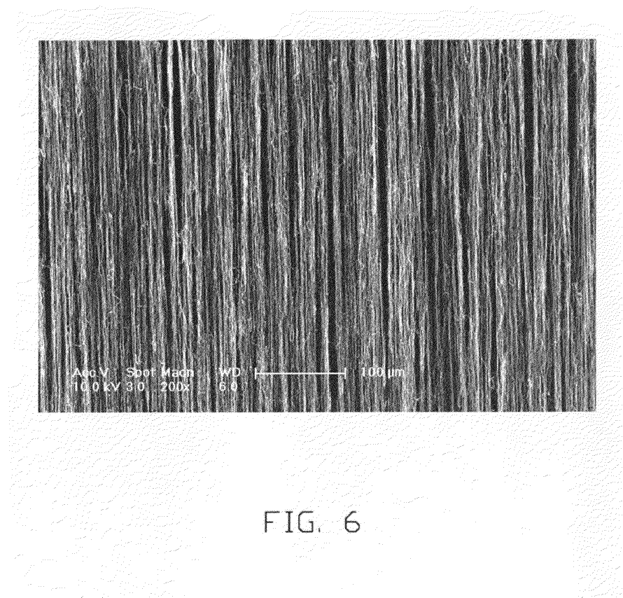

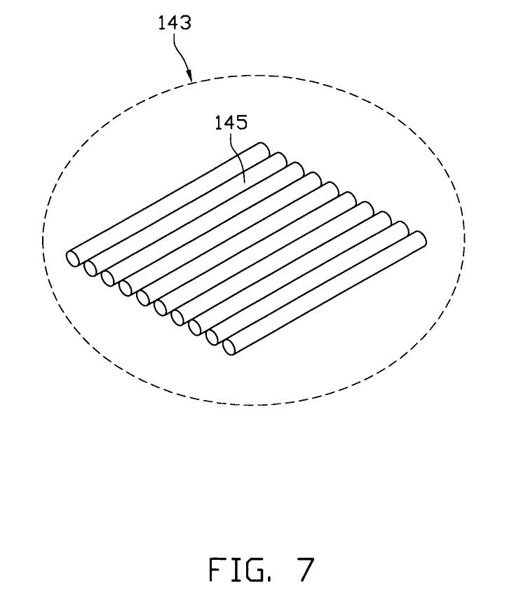

Referring to FIGS. 6 and 7, the drawn carbon nanotube film includes a plurality of successively oriented carbon nanotube segments 143 joined end-to-end by van der Waals attractive force therebetween. Each carbon nanotube segment 143 includes a plurality of carbon nanotubes 145 parallel to each other, and combined by van der Waals attractive force therebetween. The carbon nanotube segments 143 can vary in width, thickness, uniformity and shape. The carbon nanotubes 145 in the carbon nanotube film 143 are also oriented along a preferred orientation.

When the carbon nanotube layer includes a plurality of stacked and ordered carbon nanotube film, the carbon nanotubes in different carbon nanotube film can be aligned along a same direction, or aligned parallel to different directions. An angle a between the alignment directions of the carbon nanotubes in adjacent carbon nanotube films is in the range from 0 degree to 90 degrees.

In the present embodiment, the carbon nanotubes in the carbon nanotube layer are all aligned parallel to the direction from the source electrode 115 to the drain electrode 116.

The length and width of the carbon nanotube films can be selected according to practical demands. The thickness of the carbon nanotube films can be varied in range from approximately 0.5 nanometers to approximately 100 micrometers.

It is to be understood that, the carbon nanotube layer can include at least one carbon nanotube wire. The carbon nanotube wire includes a plurality of successive and oriented carbon nanotubes joined end to end by van der Waals attractive force. The carbon nanotubes in the carbon nanotube wire are substantially aligned along a length direction of the carbon nanotube wire. The carbon nanotube wire can be twisted or untwisted. The carbon nanotube wire can be arranged from the source electrode 115 to the drain electrode 116 and forms a path between the source electrode 115 and the drain electrode 116.

A length of the semiconducting layer 114 can be in an approximate range from 1 micrometer to 100 micrometers. A width of the semiconducting layer 114 can be in an approximate range from 1 micrometer to 1 millimeter. A thickness of the semiconducting layer 114 can be in an approximate range from 0.5 nanometers to 100 micrometers. A length of the channel can be in an approximate range from 1 micrometer to 100 micrometers. A width of the channel (i.e., a distance from the source electrode 115 to the drain electrode 116) can be in an approximate range from 1 micrometer to 1 millimeter. In the present embodiment, the length of the semiconducting layer 114 is about 50 micrometers, the width of the semiconducting layer 114 is about 300 micrometers, the thickness of the semiconducting layer 114 is about 25 nanometers, the length of the channel is about 40 micrometers, and the width of the channel is about 300 micrometers.

The carbon nanotube films are adhesive due to a large specific surface area of the carbon nanotubes and the high purity of the carbon nanotube film. Thus, the carbon nanotube films can be adhesively stacked on the insulating substrate 150 directly to form a carbon nanotube layer. More specifically, the carbon nanotube films can be adhered on the insulating substrate 150 first, before forming and arranging the source electrode 115 and the drain electrode 116 along the direction of the carbon nanotubes in the carbon nanotube films. Alternatively, the source electrode 115 and the drain electrode 116 can be formed on the insulating substrate 150 firstly, before adhering the carbon nanotube films on the insulating substrate 150 along the direction from the source electrode 115 and the drain electrode 116. The carbon nanotube layer covers the source electrode 115 and the drain electrode 116.

In the present embodiment, the source electrode 115 and the drain electrode 116 are spaced from each other, disposed on the opposite sides of the carbon nanotube layer, and electrically connected to the carbon nanotube layer.

The material of the insulating layer 113 can be a rigid material such as silicon nitride (Si₃N₄) or silicon dioxide (SiO₂), or a flexible material such as polyethylene terephthalate (PET), benzocyclobutenes (BCB), or acrylic resins. A thickness of the insulating layer 113 can be in an approximate range from 5 nanometers to 100 micrometers. In the present embodiment, the insulating layer 113 is Si₃N₄.

The materials of the source electrode 115, the drain electrode 116, the gate electrode 112, or combinations of the source electrode 115, the drain electrode 116 and the gate electrode 112 are conductive. In the present embodiment, the source electrode 115, the drain electrode 116, and the gate electrode 112 are conductive films. A thickness of the conductive films can be in an approximately range from 0.5 nanometers to 100 micrometers. The material of the source electrode 115, the drain electrode 116, and the gate electrode 112 can be selected from the group consisting of metal, alloy, indium tin oxide (ITO), antimony tin oxide (ATO), silver paste, conductive polymer, or metallic carbon nanotubes. The metal or alloy can be selected from the group consisting of aluminum (Al), copper (Cu), tungsten (W), molybdenum (Mo), gold (Au), titanium (Ti), neodymium (Nd), palladium (Pd), cesium (Cs), and combinations thereof. In the present embodiment, the source electrode 115, the drain electrode 116, and the gate electrode 112 are metallic carbon nanotube films. The metallic carbon nanotube film includes single-walled carbon nanotubes, double-walled carbon nanotubes, multi-walled carbon nanotubes, and combinations thereof. A diameter of the single-walled carbon nanotubes can be in an range from about 0.5 nanometers to about 50 nanometers. A diameter of the double-walled carbon nanotubes can be in an approximate range from 1 nanometer to 50 nanometers. A diameter of the multi-walled carbon nanotubes can be in an range from about 1.5 nanometers to about 50 nanometers. The distance between the source electrode 115 and the drain electrode 116 is about 1 micrometer to about 100 micrometers. The source electrode 115, the drain electrode 116, and the gate electrode 112 using metallic carbon nanotube films are all flexible.

In use, a circuit is connected to the source lines 130, and applies a scanning voltage to the source lines 130, and applies a controlling voltage on the gate lines 140. The scanning voltage cooperates with the controlling voltage to control each of the pixel unit in the liquid crystal display. More specifically, the controlling voltage forms an electric field in the channel of the semiconducting layer 114. Accordingly, carriers exist in the channel near the gate electrode 112. The channel allows a current to flow through when the semiconducting layer 114 receives an increased Vg. Thus, the source electrode 115 and the drain electrode 116 are electrically connected, and a voltage is applied on the pixel electrode 120 connected to the drain electrode 116. The carrier mobility of the semiconducting carbon nanotubes along the length direction thereof is relatively higher, and the carbon nanotubes in the carbon nanotube layer are aligned substantially from the source electrode 115 to the drain electrode 116. Therefore, the travel path of the carriers in the semiconducting layer 114 is minimal, the carrier mobility of the thin film transistor 110 is relatively higher.

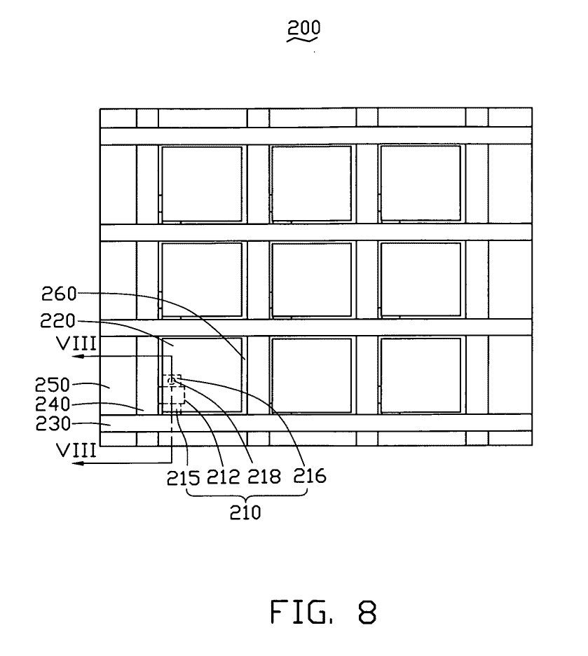

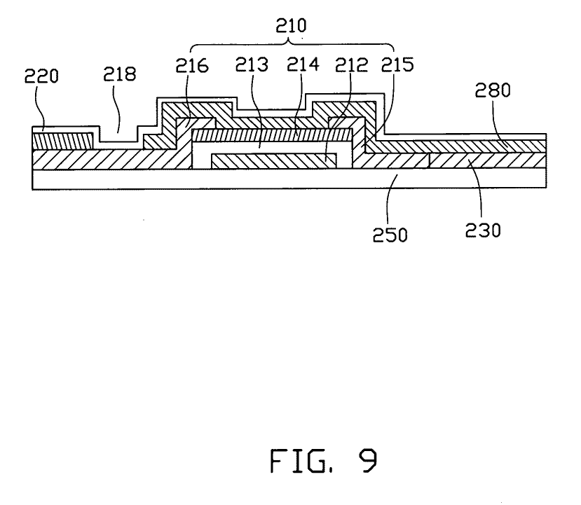

FIGS. 8 and 9 show a thin film transistor panel 200 in accordance with a second embodiment of the present invention. The thin film transistor panel 200 includes a plurality of thin film transistors 210, a plurality of pixel electrodes 220, a plurality of source lines 230, a plurality of gate lines 240, and an insulating substrate 250.

The thin film transistor 210 has a bottom gate structure. The thin film transistor 210 includes a gate electrode 212, an insulating layer 213, a semiconducting layer 214, a source electrode 215, and a drain electrode 216. The thin film transistor 210 is disposed on an insulating substrate 250.

The structure of the thin film transistor 210 in the second embodiment is similar to that of the thin film transistor 110 in the first embodiment. The difference is that, in the second embodiment, the gate electrode 212 is disposed on the insulating substrate 250. The insulating layer 213 covers the gate electrode 212. The semiconducting layer 214 is disposed on the insulating layer 213, and insulated from the gate electrode 212 by the insulating layer 213. The source electrode 215 and the drain electrode 216 are spaced apart from each other and electrically connected to the semiconducting layer 214. The source electrode 215, and the drain electrode 216 are insulated from the gate electrode 212 by the insulating layer 213. A channel is defined in the semiconducting layer 214 at a region between the source electrode 215 and the drain electrode 216.

The source electrode 215 and the drain electrode 216 can be disposed on the semiconducting layer 214 or on the insulating layer 213. More specifically, the source electrode 215 and the drain electrode 216 can be disposed on a top surface of the semiconducting layer 214, and at a same side of the semiconducting layer 214 having the gate electrode 212. In other embodiments, the source electrode 215 and the drain electrode 216 can be disposed on the insulating layer 213 and covered by the semiconducting layer 214. In other embodiments, the source electrode 215 and the drain electrode 216 can be formed on the insulating layer 213, and coplanar with the semiconducting layer 214.

The pixel electrode 220 is electrically connected with the drain electrode 216 of the thin film transistor 210. More specifically, a passivation layer 280 can be further disposed on the thin film transistor 210. The passivation layer 280 covers the thin film transistor 210 and includes a through hole 218 to expose the drain electrode 216 of the thin film transistor 210. The pixel electrode 220 covers the entire grid region 260 and the thin film transistor 210 therein, and electrically connects to the drain electrode 216 at the through hole 218. The material of the passivation layer 280 can be a rigid material such as silicon nitride (Si3N4) or silicon dioxide (SiO2), or a flexible material such as polyethylene terephthalate (PET), benzocyclobutenes (BCB), or acrylic resins. The passivation layer 280 covers the thin film transistor 210 and defines a through hole 218 to expose the drain electrode 216 of the thin film transistor 210. The pixel electrode 220 covers the entire grid region 260 and the thin film transistor 210 therein, and electrically connects to the drain electrode 216 at the through hole 218.

The thin film transistor panels provided in the present embodiments have at least the following superior properties. Firstly, the carbon nanotubes in the carbon nanotube layer has superior semiconducting properties including high carrier mobility. Thus, the thin film transistor panel has a fast response speed. Secondly, the carbon nanotube layer is tough and flexible. Thus, thin film transistor panel using carbon nanotube layers is durably and flexible, and can be used in a flexible display. Thirdly, the carbon nanotube layer is durable at high temperatures. Therefore, the thin film transistor panel using carbon nanotube layers as the semiconducting layers can be used under high temperature conditions. Fourthly, the nano-scaled carbon nanotube layer can minimize the size of the thin film transistor, and thereof, increase a resolution of the thin film transistor panel.

It is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

1. A thin film transistor panel comprising:
an insulating substrate comprising of:
a plurality of parallel source lines;
a plurality of parallel gate lines crossed with the source lines; and
a plurality of girds defined by the source lines and gate lines, each of the plurality of grids comprising of:
a pixel electrode; and
a thin film transistor comprising of:
a source electrode connected with one of the source lines defining the grid;
a drain electrode that is spaced from the source electrode and connected with the pixel electrode;
a semiconducting layer connected with the source electrode and the drain electrode, the semiconducting layer comprising a semiconducting carbon nanotube layer; and
a gate electrode connected with one of the gate lines defining the grid, and the gate electrode is insulated from the source electrode, the drain electrode, and the semiconducting layer by an insulating layer.

2. The thin film transistor panel as claimed in claim 1, wherein the semiconducting carbon nanotube layer comprises one carbon nanotube film, a plurality of stacked carbon nanotube films, or at least one carbon nanotube wire, the carbon nanotube layer comprises of a plurality of carbon nanotubes.

3. The thin film transistor panel as claimed in claim 2, wherein in the carbon nanotube film, the carbon nanotubes are disordered to form the isotropic carbon nanotube film.

4. The thin film transistor panel as claimed in claim 3, wherein the disordered carbon nanotubes are curved and entangled with each other.

5. The thin film transistor panel as claimed in claim 3, wherein the disordered carbon nanotubes are substantially parallel to a surface of the carbon nanotube film.

6. The thin film transistor panel as claimed in claim 2, wherein in the carbon nanotube film, the carbon nanotubes are ultra-long carbon nanotubes parallel to each other.

7. The thin film transistor panel as claimed in claim 2, wherein in the carbon nanotube film, the carbon nanotubes are primarily oriented along a same direction.

8. The thin film transistor panel as claimed in claim 7, wherein the carbon nanotubes are successive and joined end to end by van der Waals attractive force.

9. The thin film transistor panel as claimed in claim 7, wherein the carbon nanotube layer comprises two or more stacked carbon nanotube films, an angle a between alignment directions of the carbon nanotubes in each two adjacent carbon nanotube films is in the range 0≦α≦90°.

10. The thin film transistor panel as claimed in claim 2, wherein the carbon nanotube wire comprises a plurality of successive and oriented carbon nanotubes joined end to end by van der Waals attractive force.

11. The thin film transistor panel as claimed in claim 10, wherein the carbon nanotube wire is twisted or untwisted.

12. The thin film transistor panel as claimed in claim 1, wherein the carbon nanotubes are selected from the group consisting of the single-walled carbon nanotubes, double-walled carbon nanotubes, and combinations thereof; and the diameters of the carbon nanotubes is less than 10 nanometers.

13. The thin film transistor panel as claimed in claim 1, wherein the grids are arranged in matrix along an X direction and a Y direction, the source electrodes are aligned along the X direction and the gate electrodes are aligned along the Y direction.

14. The thin film transistor panel as claimed in claim 1, wherein the material of the pixel electrodes comprises of a material selected from the group consisting of indium tin oxide, antimony tin oxide, indium zinc oxide, conductive polymer, metallic carbon nanotubes and combinations thereof.

15. The thin film transistor panel as claimed in claim 1, wherein an area of each pixel electrode is about 10 square micrometers to about 0.1 square millimeters.

16. The thin film transistor panel as claimed in claim 1, wherein the material of the source lines and the drain lines comprises of a material selected from the group consisting of metal, alloy, silver paste, conductive polymer, or metallic carbon nanotubes; the material of the insulating substrate comprises of a material selected from the group consisting of p-type or n-type silicon, silicon with an silicon dioxide layer formed thereon, glass, crystal, crystal with a oxide layer formed thereon, plastic, resin, and combinations thereof; the material of the source electrode, the drain electrode, and the gate electrode comprises of a material selected from the group consisting of metal, alloy, indium tin oxide, antimony tin oxide, silver paste, conductive polymer, or metallic carbon nanotubes.

17. The thin film transistor panel as claimed in claim 1, wherein a passivation layer is located on and covers the thin film transistor; the passivation layer comprises a through hole to expose the drain electrode of the thin film transistor; and the pixel electrode electrically connects to the drain electrode at the through hole.

18. The thin film transistor panel as claimed in claim 1, wherein each thin film transistor further comprising a channel, wherein the channel is defined in the semiconducting layer between the source electrode and the drain electrode, the length of the channel is in a range from about 1 microns to about 100 microns, a width of the channel is in a range from about 1 microns to about 1 millimeter, a thickness of the channel is in a range from about 0.5 nanometers to about 100 microns.

19. A thin film transistor panel, comprising:
an insulating substrate;
a plurality of source lines located on a surface of the substrate;
a plurality of gate lines insulated from and intersected with the source lines to define a plurality of grid regions;
a plurality of pixel electrodes, each grid region having at least one pixel electrode; and
a plurality of thin film transistors, each grid region having at least one thin film transistor, and each thin film transistor comprises:
a source electrode connected with one of the source lines that define the grid;
a drain electrode spaced from the source electrode and connected to the corresponding pixel electrode within the same grid;
a semiconducting carbon nanotube layer electrically connected with the source and drain electrodes; and
a gate electrode electrically connected with a gate line defining the grid, and the gate electrode is insulated from the source electrode, the drain electrode, and the semiconducting carbon nanotube layer by an insulating layer.
